(19) United States
(12) Patent Application Publication
(10) Pub. No.: US 2019/0260359 A1
(43) Pub. Date: Aug. 22, 2019

(54) TUNER AND RECTIFIER APPARATUS FOR WIRELESS POWER TRANSFER RECEIVER

(71) Applicant: NAPTILUS TECHNOLOGY LAB, S.L., Barcelona (ES)

(72) Inventors: Eduardo José ALARCON COT, Barcelona (ES); Mohamed ABDELHAMEED, Barcelona (ES); Jordi AIBAR SALA, Barcelona (ES); Rafael TERRADAS ROBLEDO, Barcelona (ES)

(21) Appl. No.: 15/967,142

(22) Filed: Apr. 30, 2018

(30) Foreign Application Priority Data
Feb. 19, 2018 (ES) 18000161.2

(51) Int. Cl. H03J 5/00; H02J 50/12

(52) U.S. Cl. CPC H03J 5/00; H02J 50/12

(57) ABSTRACT

A tuner and rectifier circuit for wireless power transfer receivers is provided using a single inductor and two switching networks. The single inductor is used for energy exchange between the receiver resonant circuit and an output energy buffer network wherein the rectification function is met. The tuning state of the receiver resonant circuit is tracked and the inductor is accordingly coupled with the receiver resonant circuit after an adaptive time period to inject an inductive reactance to the tank for tuning purpose.

### FIELD OF THE INVENTION

The present invention relates to wireless power transfer and wireless power transfer receivers and, more specifically, to a tuner and bridgeless rectifier in a compact circuit structure.

### TECHNICAL BACKGROUND AND RELATED ART

Magnetic resonance wireless power transfer (WPT) has become a reliable technology for contactless power delivery for a wide range of applications. The WPT spans a wide field of applications ranging from few milliwatts low-power sensors up to tens of kilowatts high-power electric vehicles. In WPT systems, a transmitting coils is energized by an alternating current producing a magnetic flux that is linked to one or more other receiving coils that are attached to either a stationary or moving load. In order to enhance the efficiency of WPT links while extending the power delivery distance, a resonating coils are created at the transmitter and receiver sides by compensating the coils using capacitive elements connected either in series or parallel with the corresponding coils. The transmitter and receiver resonant circuits must be tuned to the same frequency of operation in order to ensure a maximum power transmission at the highest possible efficiency.

A common problem in magnetic WPT systems is the stability and sensitivity issues when the transmitting and receiving resonant circuits are designed for high quality factor (Q) operation. It has been shown that the higher the quality factor, the higher the maximum power that could be delivered to the load. On the other hand, a high Q WPT receiver implicates high selective resonant characteristics that makes the resonant tank vulnerable to any small mismatch. The mismatch causes include, but are not limited to, frequency drifts, circuit parameter variations due to components tolerance or environmental effects, metallic or radiating proximity devices, and misalignment between coils. Any source of mismatch would deteriorate the performance of high Q WPT receivers and the power transfer capability is greatly degraded. To enable the employment of high Q resonant WPT receivers, the receivers has to be equipped by a device for compensating the potential effects of mismatch.

Solutions for this problem include adding a variable reactive element to the WPT receiver tank that could be used for tuning. This approach has been described in U.S. Pat. No. 8,093,758, where an inductor has been added to the receiver to tune or detune the resonant circuit dynamically according to the load conditions. However, this approach has been applied for the purpose of decreasing the losses of the receiver power converter at light loads. Moreover, a rectifying bridge is required.

Another approach in U.S. Pat. No. 8,183,938 disclosed a variable reactance realized in one embodiment by a saturable core inductor where the inductance value is controlled by varying a bias current to control the output power level. However, the disclosed system is used to track the tuning condition of the system while a separated power circuit is required for rectification and regulation of the output power.

Another approach posed in U.S. Pat. No. 9,236,771 where a plurality of variable capacitors is coupled or decoupled from the resonant tank through a plurality of switches in order to alter the resonance frequency of the resonant tank. However, this approach requires a large number of capacitors and switches still with limited tuning capabilities.

### SUMMARY OF THE INVENTION

This invention is meant to enable the employment of high Q resonant WPT receivers while an automatic tuning for the resonant circuit is achieved with one central inductor coupled between two switching networks whereas the rectification from alternating current to charge an output buffer is achieved using the same circuit. A compact circuit structure is configured to: sense the tuning condition of the WPT receiver tank and adaptively generate a time period synchronized with respect to the positive and negative cycles; couple the inductor with the resonant circuit to charge the inductor from the resonant voltage during a first portion of time; and couple the inductor between the resonant tank and the output energy buffer in order to rectify the energy from the resonant tank to the output buffer during a second time portion.

The invention also comprises a switch controlling circuit that senses one or more parameters from the receiver resonant circuit and respond by generating an adaptive time period accordingly; wait for the said time period and then switch one or more switches of the first switching network to couple to the receiver resonant circuit during a first time portion; and switch one or more switches of the second switching network to couple the central inductor between the receiver resonant circuit and the output buffer during a second time portion.

In another aspect, the invention discloses one of the preferred embodiments, wherein the receiver resonant circuit is coupled between a first node and a second node. An inductor coupled between a third node and a fourth node. A first switching network, comprises: a first switch coupled between the first node and the third node; and a second switch coupled between fourth node and the second node. A second switching network comprises: a first switch coupled between the fourth node and fifth node; and a second switch coupled between the third node and fifth node. An energy buffer network comprises at least one energy buffer element coupled between the fifth node and the second node. A switch controlling circuit configured to sense the voltage or current or both of the receiver resonant circuit and respond by closing one switch or more of the first and second switching network after an adaptive time period synchronized with their respective cycles of the receiver resonant voltage.

This aspect includes waiting for elapsing of the adaptive time period generated by the switch controlling circuit during the positive cycle of the resonant voltage, then the inductor is coupled between the first and the second node by closing the first and the second switches of the first switching network during a fixed or variable first time portion. In the said first time portion, the inductor charges from the receiver resonant voltage. Then, the second switch of the first switching network is opened and the first switch of the second switching network is closed to couple the inductor between the third and the fourth node during a fixed or variable second time portion. In the said second time portion, the output energy buffer is energized from the receiver resonant circuit and the inductor. This sequence is repeated during the negative cycle of the resonant voltage, where the first and second switches of the first switching network are closed to charge the inductor with a negative current, and then the first switch of the first switching network is opened and second switch of the second switching network is closed to energize the output energy buffer from the inductor during a second time portion.

In a further aspect of the invention, another embodiment of the invention is a receiver resonant circuit coupled between a first node and second node. An inductor coupled between a first node and a third node. A first switching network, comprises: a switch coupled between the third node and the second node. A second switching network, comprises: a first switch coupled between the third node and fourth node; and a second switch coupled between the third node and fifth node. An energy buffer network, comprises: a first energy buffer coupled between the fourth node and the second node; and a second energy buffer coupled between the second node and the fifth node. A switch controlling circuit configured to sense the voltage or current or both of the receiver resonant circuit and respond by closing one switch or more of the first and second switching network after an adaptive time period synchronized with their respective cycles of the receiver resonant voltage.

This aspect includes waiting for elapsing of the adaptive time period generated by the switch controlling circuit during the positive cycle of the resonant voltage, then the inductor is coupled between the first and the second node by closing the switch of the first switching network during a fixed or variable first time portion. In the said first time portion, the inductor charges from the receiver resonant voltage. Then, the switch of the first switching network is opened and the first switch of the second switching network is closed to couple the inductor between the third and the fourth node during a fixed or variable second time portion. In the said second time portion, the first energy buffer is energized from the receiver resonant circuit and the inductor. This sequence is repeated during the negative cycle of the resonant voltage, where the switch of the first switching network is closed to charge the inductor with a negative current, and then the switch of the first switching network is opened and second switch of the second switching network is closed to energize the second energy buffer from the receiver resonant voltage and the inductor during a second time portion.

The invention may also broadly consist in any new parts, elements and features referred to herein, individually or collectively, in any or all combinations of said parts, elements or features.

Brief description of the figures of the drawings

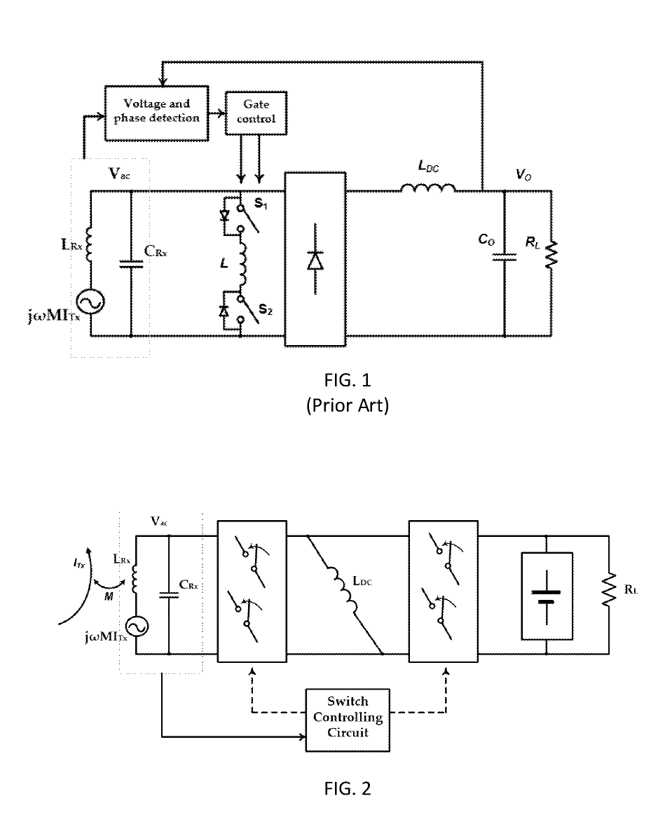

FIG. 1 shows a schematic diagram for one known embodiment of power flow control in WPT receivers.

FIG. 2 is a block diagram showing a WPT receiver connected to the tuner and rectifier device of the disclosure.

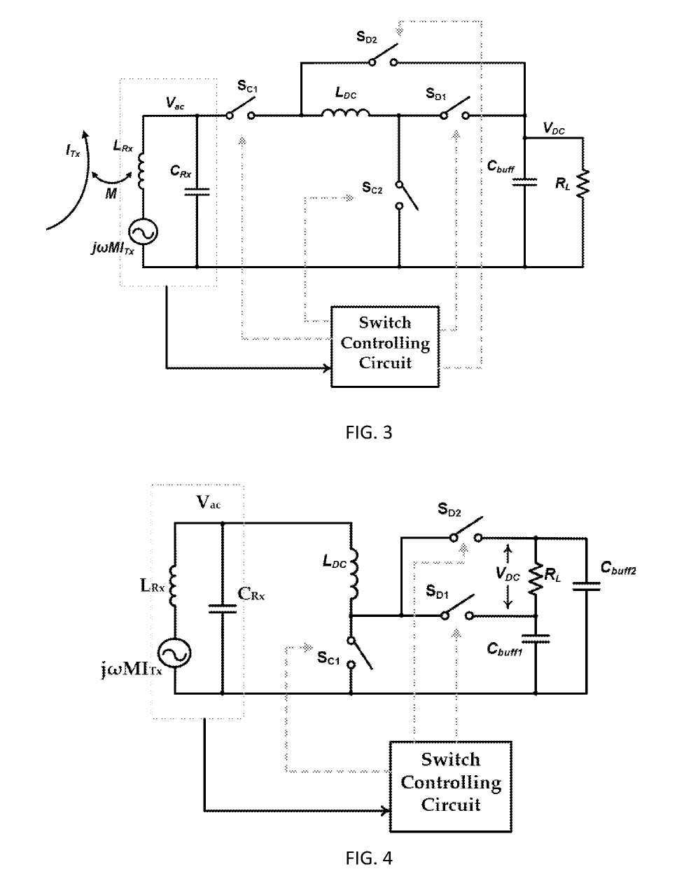

FIG. 3 is a schematic diagram of one embodiment showing of the disclosed tuner and rectifier device.

FIG. 4 is a schematic diagram showing another embodiment of a tuner and rectifier device.

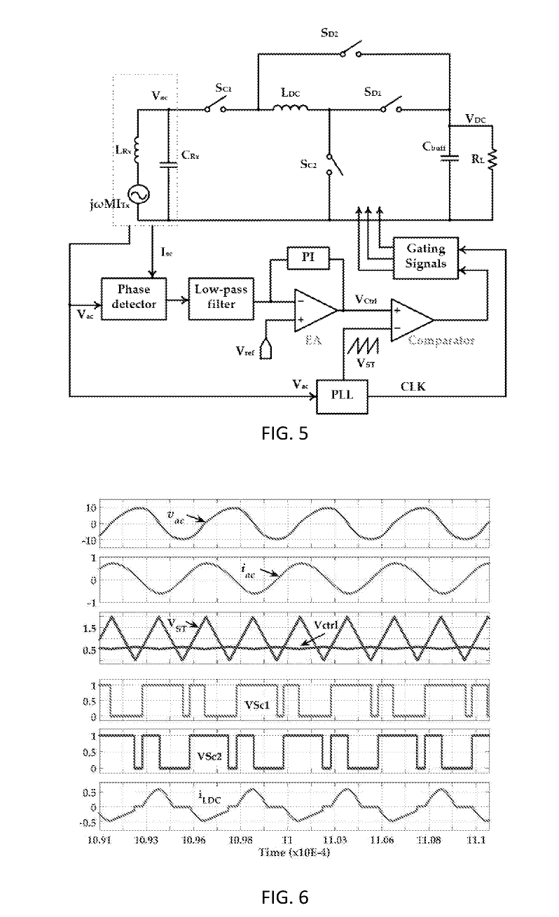

FIG. 5 shows a block diagram of the control of one of the preferred embodiments.

FIG. 6 shows the resonant tank voltage and the corresponding current in the inductor of the embodiment in FIG. 3 while showing the direct current voltage of the output buffer.

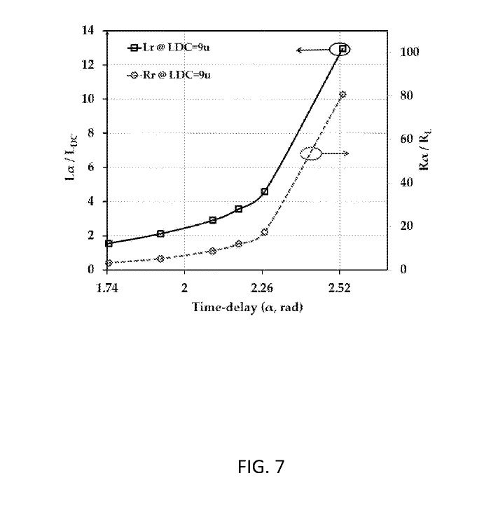

FIG. 7 shows a graph of the equivalent variable inductance versus the time-delay and the equivalent ac resistance versus the same time-delay.

### DESCRIPTION OF PREFERRED EMBODIMENTS

Referring to the drawings, the preferred embodiments of the invention are described in details. FIG. 2 shows the block diagram of a WPT receiver coupled to a tuner and rectifier device which may be considered as a general embodiment for invention. In general, the WPT receiver comprises: a WPT receiver resonant tank coupled between a first node and a second node; a central inductor LDC coupled between a third node and a fourth node; an energy buffer network coupled between a fifth node and a sixth node; a first switching network having two ports and the first port is coupled between the first and the second nodes, while the second port is coupled between the third and the fourth nodes; a second switching network having two ports and the first port is coupled between the third and the fourth nodes, while the second port is coupled between the fifth and the sixth nodes; and a switch controlling circuit that senses one or more parameters of the WPT receiver resonant tank and respond by controlling the switches of the first or the second switching networks.

The first switching network or the first switching network in FIG. 2 may contain one or more switches. The central inductor L_{DC} having two terminals coupled between the first switching networks and the second switching networks, wherein the inductor L_{DC} may be coupled in to the terminals of the receiver resonant circuit or coupled to the terminals of the energy buffer network or coupled between the receiver resonant circuit and the energy buffer network.

In operation, the switch controlling circuit in FIG. 2 may sense one or more parameters of the receiver resonant circuit to track the tuning condition of the receiver resonant circuit. The controller, in response to the tuning condition of the receiver resonant tank, may respond by closing one or more switches of the first switching network or the second switching network or both of them. Consequently, the central inductor L_{DC} may be coupled to the receiver resonant tank or between the receiver resonant tank and the energy buffer network. While the central inductor L_{DC} is coupled to the receiver resonant tank, the inductor charges either with a positive current or a negative current according to the polarity of the receiver resonant tank voltage.

The switch controlling circuit tracks the tuning condition of the receiver resonant circuit and respond by applying an adaptive time-delay that is synchronized with the start of either a positive cycle or negative cycle of the receiver resonant voltage. Then, after the elapsing of the time-delay, the switches of the first switching network or the second switching network are enabled to either couple the central inductor to the receiver resonant tank or the energy buffer network. The adaptive time-delay applied by the switch controlling circuit allow the synthesis of a variable reactance to be coupled in parallel with the WPT receiver tank. Consequently, the disclosed structure allow adaptive tuning of the receiver resonant circuit as well as energy rectification using a single central inductor LDC.

FIG. 3 shows one embodiment of the invention including an apparatus for tuning and rectification and a WPT receiver. The topology of the WPT receiver comprises a receiving coil L_{Rx} compensated by one capacitor C_{Rx} in parallel, therefrom a parallel resonant tank is constituted. The tuning and rectification apparatus is connected in parallel with the receiver resonant tank.

In FIG. 3, the tuning and rectification apparatus comprises a single inductor LDC, and four switches (S_{C1}, S_{C2}, S_{D1}, and S_{D2}) and an output capacitor Cₒᵤₜ representing an energy buffer. The switches are used to control the charging and discharging of the inductor L_{DC} by connecting the inductor L_{DC} either to the receiver resonant circuit or to the energy buffer Cₒᵤₜ or between both of them. Referring to the same figure, the apparatus includes a switch controlling circuit that senses one or more circuit parameters from the receiver resonant tank and produces the drive gating signals of the four switches.

In operation, the switch controlling circuit tracks the tuning condition of the receiver resonant tank, according to the sensed parameters, and then start the switching sequence after the elapsing of an adaptive time-delay. Then, switches S_{C1} and S_{C2} are engaged for a first time portion by enabling their drive gating signals, thereof, the inductor L_{DC} is coupled in parallel with the receiver resonant. During the said first time portion, the inductor charges with a current either going out or going in the receiver resonant circuit according to a positive cycle or negative cycle of the receiver resonant tank voltage. The first time portion may be a controlled time or uncontrolled. After that, during a second time portion, switch S_{C2} is opened and switch S_{D1} is closed to direct the energy to the energy buffer Cₒᵤₜ. The said second time portion the inductor is coupled between the receiver resonant tank and the energy buffer Cₒᵤₜ, wherein the second time portion may be controlled (or uncontrolled).

The implementation of switches (S_{C1}, S_{C2}, S_{D1}, and S_{D2}) may be realized by any semiconductor technology such as MOSFETs, IGBTs, or any other semiconductor technology that ensures a fast switching performance while the losses are kept low such that an optimum performance is guaranteed.

FIG. 4 shows a tuner and rectifier apparatus according to another embodiment of the invention including a WPT receiver comprises a receiving coil L_{Rx} compensated by one capacitor C_{Rx} in parallel, therefrom a parallel resonant tank is constituted. The tuning and rectification apparatus comprises a single inductor L_{DC}, and four switches (S_{C1}, S_{D1}, and S_{D2}) and two output capacitors C_{buff1} and C_{buff2} representing the energy buffer network. The switch S_{C1} controls the charging of the inductor L_{DC} from the receiver resonant tank while switches S_{D1} and S_{D2} controls the de-energization of inductor L_{DC} whereas the energy is rectified to one of the output capacitors. A switch controlling circuit that senses one or more circuit parameters from the receiver resonant tank and respond by selectively switch S_{C1}, S_{D1}, and S_{D2} accordingly through the drive gating signals.

The switch controlling circuit in FIG. 4 tracks the tuning condition of the receiver resonant tank by sensing one or more parameters including a voltage or current or both of them. In order to adjust the reactive part synthesized by the circuit, the switch controlling circuit respond by generating an adaptive time delay in order to delay the engagement of the inductor L_{DC} to the receiver resonant circuit. It has been found that delaying the current passing out of the receiver resonant tank with respect to the receiver tank voltage synthesizes an inductive reactance loading to the receiver resonant tank. The synthesized inductive reactance is a function of the time-delay after which the inductor L_{DC} is engaged to the receiver resonant tank. In general, the switch controlling circuit adaptively track the tuning condition of the receiver resonant tank and respond by either increasing or decreasing the time-delay in order to synthesize a variable inductive reactance to retune the receiver tank.

In a positive cycle of the receiver resonant voltage, the switch controlling circuit delay the switching for an adaptive time-delay, then engage the inductor L_{DC} to the receiver tank by closing switch S_{C1} to charge the inductor during a first time portion. At the end of the first time portion which may be controlled (or uncontrolled), switch S_{C1} is opened and switch S_{D1} is closed for a second time portion, wherein the inductor L_{DC} is coupled between the receiver resonant tank and the first output capacitor C_{buff1} in order to rectify the energy to the output.

The same switching sequence is followed during the negative cycle of the receiver resonant voltage, after the elapsing of the adaptive time-delay, the inductor L_{DC} is engaged to the receiver resonant tank during a first time portion. The second time portion starts by opening switch S_{C1} and close switch S_{D2} to couple the inductor L_{DC} between the receiver resonant tank and the second output capacitor C_{buff2} to the rectify a second portion of the receiver tank energy. The final rectified output voltage may be the summation of the voltage of C_{buff1} and C_{buff2} wherein the load may be coupled between the two capacitors.

FIG. 5 illustrates the tuner and rectifier apparatus in the embodiment of FIG. 3 wherein the switch controlling circuit may be replaced by an embodiment shown in the figure. A possible MOSEFT based realization for switches S_{C1}S_{C2}, S_{D1} and S_{D2} is also indicated in the schematic diagram. The switches realization shown in the figure may be considered as an exemplary embodiment, thereof the switches may be realized with a different technology without departing from the scope of the invention.

The switch controlling circuit, in FIG. 5, comprises a phase detector, low-pass filter, error amplifier (EA), phase locked loop (PLL), comparator and gating block. The control approach is designed based on sensing the receiver resonant tank voltage v_{ac} and the resonant current i_{ac}, wherein the control loop ensures that v_{ac} lags the resonant current i_{ac} by 90°, thereof the receiver tank fully-tuned condition is reached.

The output of the phase detector that represents the phase difference between v_{ac} and i_{ac} may be compared to a fixed reference voltage V_{ref} that corresponds to a phase lag of 90°. Then, the dc level coming from the error amplifier is compared with a sawtooth to produce the value of the time-delay α.

The full system including the invention embodiment and the exemplary control shown in FIG. 5 is simulated to illustrate the operation. The simulation waveforms in FIG. 6 shows the receiver resonant tank voltage v_{ac}, the receiver resonant current i_{ac}, the control output signal V_{ctri}, the sawtooth signal V_{ST}, the gating signals of S_{C1} and S₂, and the inductor current i_{LDC}. According the aforementioned operation, the control output signal V_{ctrl}, is compared with the sawtooth signal V_{ST} to result in the correct delay-time value α corresponding a specific synthesizable inductance L_{α}. The said synthesizable inductance L_{α} is necessary for ensuring that the receiver resonant tank is fully-tuned.

FIG. 7 shows the ration between the equivalent synthesizable inductance L_{α} and the inductance L_{DC} (L_{α}/L_{DC}) versus the time-delay a in radian. It is clear that the equivalent synthesizable inductance L_{α} increases monotonically as the time-delay increases over a wide range extends between 2× to more than 12× of the actual inductance used L_{DC}. Moreover, the same figure shows the plot of the ratio between equivalent ac resistance R_{α} and the output load resistance R_{L} versus time-delay α in radian. It is shown that R_{α} also is a function of the time-delay α wherein the effect could be seen as a variation in the output power of the WPT receiver circuit, however if the first time portion for charging the inductor L_{DC} is controlled, the value of R_{α} could be adapted accordingly toward a constant value that corresponds to a constant output power.

1. A wireless power transfer receiver magnetically coupled to a transmitter, configured for self-tuning and voltage rectification, comprising:
A resonant tank comprising a receiving coil linked by magnetic flux generated by an external transmitting coil, and one or more capacitive elements, wherein the receiving coil and one or more capacitive elements are all connected in parallel
A central inductor configured to process electrical energy and coupled between a first switching network and a second switching network
A first switching network configured to exchange energy between the receiver resonant circuit and the central inductor, and a second switching network configured to exchange energy between the central inductor and energy buffer
An energy buffer network comprising one or more energy storage element, to supply a load coupled to the terminals energy buffer network
A switch controlling circuit configured to control the first switching network and the second switching network.

2. The wireless power transfer receiver in claim 1, wherein the switch controlling circuit is configured to:
Close one or more switches of the first switching network to electrically connect the inductor in parallel with the receiver resonant circuit during a portion of the positive cycle of the resonant voltage, allowing the inductor to charge with a positive current
Maintain one or more switches of the first switching network closed and close one or more switches from the second switching network during a second portion of the positive cycle, allowing the inductor to be coupled between the receiver resonant circuit and the energy buffer network
Close one or more of the first switching network to electrically couple the central inductor in parallel with the receiver resonant circuit during a portion of the negative cycle of the resonant voltage, allowing the inductor to charge with a negative current
Maintain one or more switches of the first switching network closed and close one or more switches from the second switching network during a second portion of the negative cycle, allowing the inductor to be coupled between the receiver resonant circuit and the energy buffer network.

3. The wireless power transfer receiver in claim 1, wherein the switch controlling circuit is configured to close one or more switches from the first switching network or the second switching network by sensing voltage or current or both in the receiver resonant circuit to track a fully-tuned state of the receiver resonant circuit.

4. The wireless power transfer receiver in claim 3, wherein :
The switch controlling circuit responds by adaptively switching one or more switches of the first switching network after an adaptive time period for a first time portion of a positive cycle or negative cycle of the resonant voltage, allowing the inductor to charge with a positive current or negative current,

5. The wireless power transfer receiver in claim 4, wherein:
The switch controlling circuit adaptively switching one or more switches of the first switching network after an adaptive time period , wherein the same time period is engaged equally during positive cycle and negative cycle of the receiver resonant voltage, and
The adaptive time period counts from the starting of the positive cycle or negative cycle of the receiver resonant voltage, and
The adaptive time period during positive cycle or negative cycle finishes before the starting of the subsequent time period in the subsequent positive cycle or negative cycle of the receiver resonant voltage.

6. The wireless power transfer receiver in claim 4, wherein the switch controlling circuit is configured to:
sense one or more voltages or currents in the receiver resonant circuit to track the fully-tuned state of the receiver resonant circuit, and
Adaptively generate a variable switching time period to switch one or more of the switches of the first switching network, and
The variable switching time period allows a variable inductive reactance to be injected in parallel with the receiver resonant tank to control the tuning state.

7. The wireless power transfer receiver in claim 4, wherein:
The switch controlling circuit is configured to sense one or more voltages or currents in the receiver resonant circuit, and
Adaptively close one or more switches of the first switching network to electrically couple the inductor in parallel with the receiver resonant circuit after an adaptive time period, to allow the inductor to charge from the receiver resonant voltage during a first time portion of the resonant voltage, and
Maintain one or more switches of the first switching network closed and close one or more switches from the second switching network during a second time portion of the resonant voltage, allowing the inductor to be coupled between the receiver resonant circuit and one or more storage elements of the energy buffer network.

8. The wireless power transfer receiver in claim 1, wherein the receiver resonant circuit is coupled between a first node and a second node, comprises:
An inductor coupled between a third node and a fourth node
A first switching network, comprises:
(1) a first switch coupled between the first node and the third node,
(2) a second switch coupled between fourth node and the second node
A second switching network comprises:
(1) A first switch coupled between the fourth node and fifth node,
(2) A second switch coupled between the third node and fifth node
An energy buffer network comprises at least one energy buffer element coupled between the fifth node and the second node,
A switch controlling circuit configured to sense the voltage or current or both of the receiver resonant circuit and respond by closing one switch or more of the first and second switching network.

9. The wireless power transfer receiver in claim 8, wherein the switch controlling circuit is configured to:
track the fully-tuned state of the receiver resonant circuit by generating an adaptive time period, and
Maintain all switches opened during the said adaptive time period
close the first and second switches of the first switching network allowing the inductor to be coupled in parallel with the receiver resonant circuit during a first time portion of the positive cycle of the receiver resonant voltage, and
couple the inductor between the receiver resonant circuit and the energy buffer network by opening the second switch of the first switching network and closing the second switch of the second switching network during a second time portion of the said positive cycle,
close the first and second switches of the first switching network after the same variable time period, allowing the inductor to be coupled in parallel with the receiver resonant circuit during a first time portion of the negative cycle of the receiver resonant voltage, and
couple the inductor to the energy buffer network by opening the first switch of the first switching network and closing the first switch of the second switching network during a second time portion of the said negative cycle.

10. The wireless power transfer receiver in claim 8, wherein the switch controlling circuit is configured to:
Generate an adaptive time period synchronized with the starting of a positive or negative cycle of the receiver resonant voltage, and
Couple the inductor in parallel with the receiver resonant tank after the adaptive time period during a first time portion, and
Couple the inductor between the receiver resonant circuit and the energy buffer network during a second time portion.

11. The wireless power transfer receiver in claim 1, wherein the receiver resonant circuit is coupled between a first node and second node, comprises:
An inductor coupled between a first node and a third node
A first switching network, comprises:
(1) A switch coupled between the third node and the second node
A second switching network, comprises:
(1) A first switch coupled between the third node and fourth node, and
(2) A second switch coupled between the third node and fifth node
An energy buffer network, comprises:
(1) A first energy buffer coupled between the fourth node and the second node
(2) A second energy buffer coupled between the second node and the fifth node
A switch controlling circuit configured to sense the voltage or current or both of the receiver resonant circuit and respond by closing one switch or more of the first and second switching network.

12. The wireless power transfer receiver in claim 11, wherein the switch controlling circuit is configured to:
track the fully-tuned state of the receiver resonant circuit by adaptively generate an adaptive time period, and
Maintain all switches opened during the said adaptive time period,
close the switch of the first switching network allowing the inductor to be coupled in parallel with the receiver resonant circuit during a first time portion of the positive cycle of the receiver resonant voltage, and
couple the inductor between the receiver resonant circuit and the first energy buffer by opening the switch of the first switching network and closing the first switch of the second switching network during a second time portion of the said positive cycle,
close the switch of the first switching network after the same variable time period, allowing the inductor to be coupled in parallel with the receiver resonant circuit during a first time portion of the negative cycle of the receiver resonant voltage, and
couple the inductor between the receiver resonant circuit and the second energy buffer by opening the switch of the first switching network and closing the second switch of the second switching network during a second time portion of the said negative cycle.

13. The wireless power transfer receiver in claim 11, wherein the switch controlling circuit is configured to:
Generate an adaptive time period synchronized with the starting of a positive or negative cycle of the receiver resonant voltage, and
Couple the inductor in parallel with the receiver resonant tank after the adaptive time period during a first time portion, and
Couple the inductor between the receiver resonant circuit and one element of the energy buffer network during a second time portion.
